(19) United States
(12) Patent Application Publication
(10) Pub. No.: US 2007/0030724 A1
(43) Pub. Date: Feb. 8, 2007

(54) MEMORY ELEMENT AND MEMORY

(76) Inventors: Masanori Hosomi, Kanagawa (JP); Hiroyuki Ohmori, Kanagawa (JP); Hiroshi Kano, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/460,135

(22) Filed: Jul. 26, 2006

(30) Foreign Application Priority Data
Aug. 5, 2005 (JP) P2005-228902

(51) Int. Cl. G11C 11/00

(52) U.S. Cl. 365/158

(57) ABSTRACT

The present invention provides a memory element including a memory layer that holds information based on a magnetization state of a magnetic substance, and a magnetization pinned layer that is provided for the memory layer with intermediary of an intermediate layer therebetween, the intermediate layer being composed of an insulator. Spin-polarized electrons are injected in a layer-stacking direction to thereby change a direction of magnetization of the memory layer, so that information is recorded in the memory layer. At least one ferromagnetic layer included in the memory layer is composed mainly of CoFeTa, and has Ta content in a range from 1 atomic percent (at %) to 20 at %.

### CROSS REFERENCES TO RELATED APPLICATIONS

The present invention contains subject matter related to Japanese Patent Application JP 2005-228902 filed in the Japanese Patent Office on Aug. 5, 2005, the entire contents of which being incorporated herein by reference.

### BACKGROUND OF THE INVENTION

1. Field of the Invention

The present invention relates to a memory element that includes a memory layer for storing the magnetization state of a ferromagnetic layer as information and a magnetization pinned layer of which magnetization direction is fixed, and changes the magnetization direction of the memory layer in response to current flow therethrough. The invention also relates to a memory that includes the memory element and is suitably used as a nonvolatile memory.

2. Description of the Related Art

In information apparatuses such as computers, high speed and high density DRAMs are widely used as a random access memory.

However, the DRAM is a volatile memory and therefore loses information when power is cut off. Accordingly, the need for nonvolatile memories, which do not involve the information loss, is increasing.

As a candidate of the nonvolatile memories, magnetoresistive random access memories (MRAM), which record information based on magnetization of a magnetic substance, have been drawing attention, and development thereof is being promoted (refer to e.g. Nikkei Electronics, p. 164-171, Issue No. 12, February 2001).

In the MRAM, current is applied to two kinds of address lines (word line and bit line) that are substantially perpendicular to each other, and thus a current magnetic field is generated from the respective address lines. This current magnetic field leads to the reversal of magnetization of the magnetic layer in the magnetic memory element at the intersection between the address lines, so that information is recorded.

FIG. 8 is a schematic diagram (perspective view) of a typical MRAM.

In the respective regions separated by element isolation layers 102 in a semiconductor base 110 such as a silicon substrate, drain regions 108, source regions 107 and gate electrodes 101 included in selection transistors for selecting the respective memory cells are formed.

Above the gate electrodes 101, word lines 105 extending in the anteroposterior direction in the drawing are provided.

The drain region 108 is formed in common to two selection transistors that are laterally arranged in the drawing, and is connected to an interconnect 109.

Between the word line 105 and a bit line 106 that is provided above and extends in the lateral direction in the drawing, a magnetic memory element 103 that includes a memory layer of which magnetization direction can be reversed is disposed. The magnetic memory element 103 is formed of e.g. a magnetic tunnel junction element (MTJ element).

The magnetic memory element 103 is electrically coupled to the source region 107 via a horizontally extending bypass line 111 and a vertically extending contact layer 104.

When current is applied to the word line 105 and the bit line 106, a current magnetic field is applied to the magnetic memory element 103. This magnetic field application reverses the magnetization direction of the memory layer in the magnetic memory element 103, which allows information recording.

In order for a magnetic memory such as the MRAM to stably hold recorded information, the magnetic layer (memory layer) for recording information has a certain coercivity.

In addition, to rewrite recorded information, a certain amount of current needs to be applied to the address lines.

The current value necessary for magnetization reversal shows a tendency of increasing the value as the size of elements included in the MRAM decreases. However, the width reduction of the address lines accompanying the element size decrease precludes a sufficient amount of current from flowing through the address lines.

Consequently, as a memory that can reverse magnetization with a small current, a memory employing magnetization reversal attributed to spin injection has been attracting attention. The following document examples describe this type of a memory: Japanese Patent Laid-open No. 2003-17782; U.S. Pat. No. 6,256,223; Phys. Rev. B 54. 9353 (1996); and J. Magn. Mat. 159. L1 (1996).

The outline of the magnetization reversal attributed to spin injection is as follows: electrons of which spins have been polarized due to passage of the electrons through a magnetic substance are injected into another magnetic substance so that magnetization reversal is caused in the magnetic substance.

For example, current is applied to a giant magnetoresistance effect element (GMR element) or a magnetic tunnel junction element (MTJ element) in the direction perpendicular to the film plane of the element, which allows reversal of the magnetization direction in at least one magnetic layer in the element.

The magnetization reversal attributed to spin injection has an advantage that even when elements are miniaturized, magnetization reversal can be achieved without involving a current increase.

FIGS. 6 and 7 are schematic diagrams illustrating a memory that utilizes the above-described magnetization reversal attributed to spin injection. FIG. 6 is a perspective view while FIG. 7 is a sectional view.

In the respective regions separated by element isolation layers 52 in a semiconductor base 60 such as a silicon substrate, drain regions 58, source regions 57, and gate electrodes 51 included in selection transistors for selecting the respective memory cells are formed. Of these components, the gate electrode 51 serves also as a word line extending in the anteroposterior direction in FIG. 6.

The drain region 58 is formed in common to two selection transistors that are laterally arranged in FIG. 6, and is connected to an interconnect 59.

Between the source region 57 and a bit line 56 that is provided above and extends in the lateral direction in FIG. 6, a memory element 53 that includes a memory layer of which magnetization direction can be reversed due to spin injection is disposed.

The memory element 53 is formed of e.g. a magnetic tunnel junction element (MTJ element). Referring to FIG. 7, the memory element 53 includes magnetic layers 61 and 62. Of these two magnetic layers 61 and 62, one magnetic layer is used as a magnetization pinned layer in which the magnetization direction is fixed, while the other magnetic layer is used as a magnetization free layer of which magnetization direction can be changed, i.e., as a memory layer.

The memory element 53 is coupled to the bit line 56 and the source region 57 via upper and lower contact layers 54, respectively. This structure allows current to flow through the memory element 53 so that the magnetization direction in the memory layer can be reversed due to spin injection.

Such a memory employing the magnetization reversal attributed to spin injection has a characteristic that the device structure thereof can be simplified and therefore the density can be enhanced compared with a typical MRAM shown in FIG. 8.

In addition, the magnetization reversal attributed to spin injection offers an advantage that the current value for writing does not increase even when the size of elements is decreased, unlike a typical MRAM that employs an external magnetic field for magnetization reversal.

In the typical MRAM, writing lines (word line and bit line) are provided separately from a memory element, and information writing (recording) is carried out by use of a current magnetic field generated when current is applied to the writing lines. Therefore, a sufficient amount of current necessary for writing can be applied to the writing lines.

In contrast, in the memory that employs the magnetization reversal attributed to spin injection, it is necessary that the spin injection be implemented via the current flowing through the memory element for reversal of the magnetization direction of the memory layer.

Information writing (recording) is carried out by thus directly applying current to the memory element, and a memory cell is constructed by coupling the memory element to a selection transistor, for selection of the memory cell for which writing is to be implemented. Therefore, the magnitude of the current flowing through the memory element is limited by the maximum allowable magnitude of the current applied to the selection transistor (saturation current of the selection transistor).

Consequently, writing is carried out with a current equal to or smaller than the saturation current of the selection transistor. Therefore, it is necessary that the spin injection efficiency is enhanced to reduce the current to be applied to the memory element.

Furthermore, a large magnetoresistance ratio needs to be ensured in order to obtain a large read-out signal. For the ensuring of a large magnetoresistance ratio, it is effective to construct a memory element in which intermediate layers that are in contact with the both planes of the memory layer are tunnel insulating layers (tunnel barrier layers).

The use of tunnel insulating layers as the intermediate layers however imposes a limitation on the amount of current flowing through the memory element in order to prevent of insulation breakdown of the tunnel insulating layers. Also from this viewpoint, the current at the time of spin injection needs to be suppressed.

Therefore, in the memory element in which the magnetization direction of a memory layer is reversed through spin injection, there is a need to improve the spin injection efficiency for a decrease of the requisite current.

As a measure for suppressing the current at the time of spin injection, a memory element having the following structure has been proposed in US Published Application No. 2004/0027853. Specifically, this memory element has, instead of a multilayer structure of pinned layer/intermediate layer/memory layer employed in a typical magnetic tunnel junction element, a multilayer structure of pinned layer/intermediate layer/memory layer/intermediate layer/pinned layer in which the pinned layers above and below the memory layer have magnetization directions opposite to each other.

Furthermore, this patent document explains that these opposite magnetization directions of the upper and lower pinned layers allow doubling of the spin injection efficiency.

### SUMMARY OF THE INVENTION

It would be possible in theory that the structure described in this patent document allows the doubling of the spin injection efficiency.

However, when the present inventors actually fabricated the memory element having the above-described structure described in the patent document and checked the properties of this memory element, results congruous with the theory of the patent document were not obtained and a sufficient improvement in the spin injection efficiency was not found.

It is desirable that the present invention is to provide a memory element that has enhanced spin injection efficiency and thus can implement writing with a decreased current value, and a memory that includes the memory element.

According to a first embodiment of the present invention, a memory element includes a memory layer that holds information based on the magnetization state of a magnetic substance, and a magnetization pinned layer that is provided for the memory layer with the intermediary of an intermediate layer composed of an insulator therebetween. Spin-polarized electrons are injected in the layer-stacking direction to thereby change the magnetization direction of the memory layer, so that information is recorded in the memory layer. The memory layer is composed mainly of CoFeTa, and has Ta content in the range from 1 atomic percent (hereinafter, abbreviated as at %) to 20 at %.

According to a second embodiment of the present invention, a memory includes a memory element that has a memory layer for holding information based on the magnetization state of a magnetic substance, and two kinds of interconnects that intersect with each other. This memory element has the same structure as that of the memory element of the first embodiment. The memory element is disposed between the two kinds of interconnects and near the intersection of the two kinds of interconnects. A current in the layer-stacking direction flows through the memory element via the two kinds of interconnects.

According to the configuration of the memory element of the first embodiment, a memory layer that holds information based on the magnetization state of a magnetic substance is included, and a magnetization pinned layer is provided for this memory layer with the intermediary of an intermediate layer therebetween. For this memory element, spin-polarized electrons are injected in the layer-stacking direction to thereby change the magnetization direction of the memory layer, so that information is recorded in the memory layer. Therefore, by applying a current in the layer-stacking direction to inject spin-polarized electrons, information recording attributed to the spin injection can be carried out.

Furthermore, since the intermediate layer is composed of an insulator, and the memory layer is composed mainly of CoFeTa and has Ta content in the range from 1 at % to 20 at %, the spin injection efficiency can be greatly increased. Thus, the amount of the current (threshold current) necessary for reversal of the magnetization direction of the memory layer due to spin injection can be decreased.

According to the configuration of the memory of the second embodiment, a memory element that includes a memory layer for holding information based on the magnetization state of a magnetic substance, and two kinds of interconnects that intersect with each other are included. This memory element has the same structure as that of the memory element of the first embodiment, and is disposed between the two kinds of interconnects and near the intersection of the two kinds of interconnects. Furthermore, a current in the layer-stacking direction flows through the memory element via the two kinds of interconnects. Thus, information recording attributed to spin injection can be carried out by applying a current in the layer-stacking direction of the memory element via the two kinds of interconnects to inject spin-polarized electrons.

In addition, the amount of the current (threshold current) necessary for reversal of the magnetization direction of the memory layer in the memory element due to spin injection can be decreased.

According to the above-described embodiments of the present invention, the amount of the current (threshold current) necessary for reversal of the magnetization direction of a memory layer can be suppressed, which can reduce the amount of the current necessary for information recording.

Thus, a sufficient margin of error for operation of the memory element can be achieved, and therefore the memory element can be operated at high speed without errors.

Furthermore, the need to apply a large voltage is eliminated, which causes no breakdown of an insulator as an intermediate layer.

Therefore, a highly reliable memory that stably operates can be achieved.

Moreover, the power consumption of the entire memory can be reduced.

### BRIEF DESCRIPTION OF THE DRAWINGS

FIG. 1 is a schematic structural diagram (perspective view) of a memory according to one embodiment of the present invention;

FIG. 2 is a sectional view of a memory element shown in FIG. 1;

FIG. 3 is a sectional view of a memory element according to another embodiment of the invention;

FIG. 4A is a diagram showing the relationship between the Ta addition amount (at %) and the MR ratio of each sample of a first experiment;

FIG. 4B is a diagram showing the relationship between the Ta addition amount (at %) and the reversal current density of each sample of the first experiment;

FIG. 5A is a diagram showing the relationship between the addition amounts of Ta and B (at %) and the MR ratio of each sample of a second experiment;

FIG. 5B is a diagram showing the relationship between the addition amounts of Ta and B (at %) and the reversal current density of each sample of the second experiment;

FIG. 6 is a schematic structural diagram (perspective view) of a memory that utilizes magnetization reversal attributed to spin injection;

FIG. 7 is a sectional view of the memory shown in FIG. 6; and

FIG. 8 is a perspective view schematically illustrating the structure of a MRAM in related art.

### DETAILED DESCRIPTION OF THE PREFERRED EMBODIMENTS

Prior to descriptions of specific embodiments of the present invention, the outline of the invention will be described below.

In the invention, the magnetization direction of a memory layer in a memory element is reversed through the above-described spin injection so that information is recorded. The memory layer is composed of a magnetic substance such as a ferromagnetic layer, and holds information based on the magnetization state (magnetization direction) of the magnetic substance.

The basic operation for reversing the magnetization direction of the magnetic layer through spin injection is to apply a current larger than a certain threshold value to a memory element formed of a giant magnetoresistance effect element (GMR element) or a tunnel magnetoresistance effect element (MTJ element) in the direction perpendicular to the film plane of the element. The polarity (direction) of the current depends on the direction into which magnetization is to be reversed.

When a current of which absolute value is smaller than the threshold value is applied, the magnetization reversal is not caused.

The threshold value Ic of the current necessary for reversal of the magnetization direction of a magnetic layer through spin injection is expressed by the following Equation (1) phenomenologically (refer to e.g. F. J. Albert et al., Appl. Phys. Lett., 77, p. 3809, 2000).
I_{c}^{±}=kMsV(H_{K}^{effective})/g^{±} (1)

In Equation (1), k is a constant, g^{±} is the material-specific reversal coefficient corresponding to the positive and negative current polarities, H_{K}^{effective} is effective magnetic anisotropy, Ms is the saturation magnetization of the magnetic layer, and V is the volume of the magnetic layer.

The invention utilizes the fact that the current threshold value can be set optionally by adjusting the volume V of the magnetic layer, the saturation magnetization Ms of the magnetic layer, and the magnitude of the effective magnetic anisotropy as indicated by Equation (1).

Furthermore, a memory element is constructed that includes a magnetic layer (memory layer) capable of holding information based on its magnetization state and a magnetization pinned layer of which magnetization direction is fixed.

An example of the current threshold for changing the magnetization state of a memory layer in an actual element is as follows: in a substantially elliptical giant magnetoresistance effect electrode (GMR element) of which memory layer has a thickness of 2 nm and a planar pattern size of 120-130 nm by 100 nm, the positive threshold value +Ic is +0.6 mA, the negative threshold value −Ic is −0.2 mA, and the current density corresponding to the threshold values is about 6×10⁶ A/cm². These values substantially match Equation (1) (refer to Yagami et al., Journal of the Magnetics Society of Japan, Vol. 28, No. 2, p. 149, 2004).

On the contrary, in a typical MRAM that employs a current magnetic field for magnetization reversal, a writing current on the order of several milliamperes is necessary.

In contrast, employing spin injection for magnetization reversal offers a sufficiently decreased writing current threshold as described above, and therefore is advantageous for reduction of power consumption of integrated circuits.

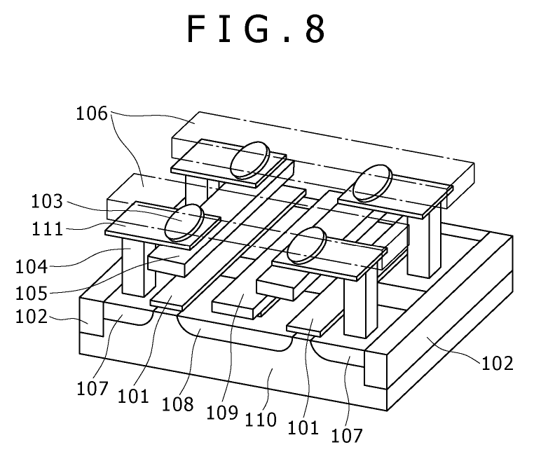

In addition, employing spin injection eliminates the need to provide lines which are used in a typical MRAM for generating a current magnetic field (the lines 105 in FIG. 8), and hence is advantageous over the typical MRAM also in terms of the integration degree.

However, as described above, in the memory that employs the magnetization reversal attributed to spin injection, it is necessary that the spin injection be implemented via the current flowing through the memory element for reversal of the magnetization direction of the memory layer.

Information writing (recording) is carried out by thus directly applying current to the memory element, and a memory cell is constructed by coupling the memory element to a selection transistor, for selection of the memory cell for which writing is to be implemented. Therefore, the magnitude of the current flowing through the memory element is limited by the maximum allowable magnitude of the current applied to the selection transistor (saturation current of the selection transistor).

Consequently, writing is carried out with a current equal to or smaller than the saturation current of the selection transistor. Therefore, it is necessary that the spin injection efficiency is enhanced to reduce the current to be applied to the memory element.

The present inventors therefore have made various studies to enhance the spin injection efficiency, and as the result, the inventors have found the following fact. Specifically, by specifying the material of at least one ferromagnetic layer included in a memory layer and defining the composition in the layer, the spin injection efficiency is improved and thus the current density necessary for reversal of the magnetization direction of the memory layer is decreased.

Consequently, according to an embodiment of the present invention, at least one ferromagnetic layer included in a memory layer is composed mainly of CoFeTa, and has Ta content in the range from 1 at % to 20 at %.

Thus, the spin injection efficiency can be enhanced, and hence the current density necessary for reversal of the magnetization direction of the memory layer can be decreased.

Alternatively, another configuration is also available in which at least one ferromagnetic layer included in a memory layer is composed mainly of CoFeTaB, and the Ta content and B content in the ferromagnetic layer are in the range from 1 at % to 20 at %, and in the range from 10 at % to 30 at %, respectively.

The reason why mixing Ta into the memory layer can reduce the current density will be described below.

In the above-described Equation (1), the term effective magnetic anisotropy H_{K}^{effective} arises from the combination of the anisotropy field H_{K} in the in-plane direction of the magnetic layer and the anisotropy field H_{K} in the perpendicular-to-plane direction thereof. In a CoFe or CoFeB memory layer, which has magnetic anisotropy in the film plane, the anisotropy field H_{K} in the perpendicular-to-plane direction is larger than the anisotropy field H_{K} in the in-plane direction, and the anisotropy field H_{K} in the perpendicular-to-plane direction is expressed as Ms/2.

In this case, Equation (1) is expressed as the following Equation (2).
Ic=Ms·V·(H_{K}+Ms/2)·(k/g) (2)

In Equation (2), H_{K} is much less than Ms.

Equation (2) indicates that decreasing the saturation magnetization Ms is effective for reducing the current threshold Ic.

In the present invention, addition of Ta decreases the saturation magnetization Ms, and therefore the current threshold Ic is decreased by the amount proportional to the difference between the square of the original saturation magnetization Ms and the square of the decreased saturation magnetization Ms.

Moreover, the addition of Ta permits a smaller amount of the added element (i.e., Ta) for decreasing the saturation magnetization Ms compared with the case of adding another element, and hence can suppress a decrease of the MR ratio due to the element addition.

Therefore, due to the addition of Ta, the current threshold Ic can be reduced by decreasing the saturation magnetization Ms, while an MR ratio equivalent to values in the past can be ensured.

Furthermore, in order to maintain characteristics as a memory, a thermal stability index Δ larger than a certain value needs to be ensured so that magnetization reversal due to thermal is not caused. Typically, the index Δ needs to be at least 60. The index Δ is expressed by the following Equation (3).
Δ=Ms·V·H_{K}·(½kT) (3)

In Equation (3), k is the Boltzmann constant, and T is a temperature.

Equation (3) indicates that the thermal stability index Δ decreases as the saturation magnetization Ms decreases.

Therefore, the anisotropy field H_{K} is increased in order to prevent a decrease of the thermal stability index Δ associated with a decrease of the saturation magnetization Ms.

The anisotropy field H_{K} can be increased by decreasing the minor axis size of the element to thereby increase the aspect ratio of the element. Furthermore, increasing the anisotropy field H_{K} of the ferromagnetic material of the memory layer is also available. This can be achieved by combining a memory layer composed of CoFeTa or CoFeTaB with another ferromagnetic layer having a large anisotropy field H_{K}.

As described above, according to an embodiment of the present invention, at least one ferromagnetic layer included in a memory layer is composed of a material that arises from addition of Ta to CoFe or CoFeB. Thus, the magnetization reversal current can be reduced while the requisite MR ratio and thermal stability are ensured.

A simple method for adding Ta is to fabricate a CoFeTa or CoFeTaB sputtering target. However, a CoFeTa or CoFeTaB target made by typical hot-press sintering for obtaining an alloy target involves a large composition bias, and therefore possibly results in an inhomogeneous thin film. In the case of a method of melting an alloy in vacuum and casting the melted alloy, the cast ingot is brittle and therefore it is difficult to form recrystallized grains through rolling, which enforces the use of the as-cast ingot as an alloy target. Accordingly, although the method of using an alloy target may be available, it is difficult to fabricate the target itself.

For that reason, as the method for adding Ta, a method of providing a Ta ultra-thin film in a CoFe or CoFeB layer or a method of mixing Ta through co-sputtering is employed. The provision of a Ta ultra-thin film in a CoFe or CoFeB layer allows highly reproducible adjustment of the Ta addition amount.

In order to ensure the requisite MR ratio, it is desirable for the memory layer to be formed so that Ta is absent in the interface of the memory layer in direct contact with a tunnel insulating layer (tunnel barrier layer).

The amount of Ta added to a CoFe or CoFeB layer is in the range from 1 at % to 20 at %.

Although the saturation magnetization Ms decreases as the Ta addition amount increases, an addition amount above 20 at % leads to a significantly decreased saturation magnetization Ms, which makes it difficult to ensure a high thermal stability index Δ by increasing the anisotropy field H_{K}. Therefore, the magnetization of the memory layer becomes too small, which deteriorates the function as a memory layer of a memory.

As for the lower limit of the Ta addition amount, at least 1 at % is necessary for the effect of the Ta addition to be recognized. As the Ta addition amount is increased from 1 at %, the reversal current is reduced and the thermal stability index Δ is decreased. The Ta addition amount is determined depending on the properties in accordance with memory properties.

As described above, the addition of Ta of which dose is in the range from 1 at % to 20 at % can reduce the magnetization reversal current while ensuring thermal stability (index Δ) necessary as a memory element. The reduction of the magnetization reversal current allows a decrease of the saturation current value of selection transistors. Specifically, the gate width of the transistors can be decreased, and thus the cells can be miniaturized, which can offer a high-capacity nonvolatile memory.

In terms of ensuring of magnetization and soft magnetic properties, it is preferable that the sum of the Co content and Fe content, which are ferromagnetic components, in a CoFeTa alloy be equal to or more than 80 at %.

More specifically, it is preferable that in the CoFeTa alloy, the Co content is in the range from 32 at % to 90 at % and the Fe content is in the range from 8 at % to 60 at %.

In addition, it is preferable that the sum of the Co content and Fe content, which are ferromagnetic components, in a CoFeTaB alloy be equal to or more than 60 at %.

More specifically, it is preferable that in the CoFeTaB alloy, the Co content is in the range from 20 at % to 80 at % and the Fe content is in the range from 5 at % to 55 at %.

If the sum of the Co content and Fe content is smaller than 60 at %, saturation magnetization and coercivity as those of a ferromagnetic layer are not obtained. Furthermore, in general, when the ratio of Co to Fe is in the range from 90:10 to 40:60, such favorable soft magnetic properties that magnetic anisotropy dispersion is adequately suppressed are exhibited. Therefore, also in the embodiment of the present invention, the amount ratio of Co to Fe may be set so that these Co and Fe achieve favorable properties as ferromagnetic components as described above.

In addition, in consideration of the saturation current value of selection transistors, the present invention employs a tunnel insulating layer composed of an insulator as a non-magnetic intermediate layer between the memory layer and magnetization pinned layer so that a magnetic tunnel junction (MTJ) element is formed. This is because forming an MTJ element by use of a tunnel insulating layer can offer a larger magnetoresistance change ratio (MR ratio) and therefore a larger intensity of a read-out signal compared with the case of forming a giant magnetoresistance effect (GMR) element by use of a non-magnetic conductive layer.

Furthermore, in particular, employing magnesium oxide (MgO) as the material of the tunnel insulating layer can offer a further larger magnetoresistance change ratio (MR ratio) compared with the case of employing aluminum oxide, which is typically used in elements in the past.

In general, the spin injection efficiency depends on the MR ratio: a larger MR ratio can offer enhanced spin injection efficiency and therefore a reduced magnetization reversal current density.

Therefore, when magnesium oxide is used as the material of a tunnel insulating layer that is an intermediate layer, the threshold current of writing due to spin injection can be reduced, and thus information can be written (recorded) with a small current. Furthermore, the intensity of a read-out signal can be enhanced.

Thus, the threshold current of writing due to spin injection can be reduced while a high MR ratio (TMR ratio) is ensured, and thus information can be written (recorded) with a small current. Furthermore, the intensity of a read-out signal can be enhanced.

Regarding the tunnel insulating layer formed of a magnesium oxide (MgO) film, it is more desirable that the MgO film is crystallized and the crystal orientation thereof be maintained at 001 direction.

In the present invention, the intermediate layer between the memory layer and magnetization pinned layer may be composed of, instead of magnesium oxide (tunnel insulating layer), any of various insulators, dielectrics, and semiconductors, such as aluminum oxide, aluminum nitride, SiO₂, Bi₂O₃, MgF₂, CaF, SrTiO₂, AlLaO₃, and Al—N—O.

When magnesium oxide is used for the intermediate layer, typically the annealing temperature is as high as at least 300° C., and desirably 340-360° C. in order to obtain excellent MR properties. Such a temperature is higher than annealing temperatures for aluminum oxide (250-280° C.), which is used in the past for the intermediate layer.

This would be because a high temperature is necessary for formation of adequate internal structure and crystalline structure of magnesium oxide.

Therefore, unless a ferromagnetic material having such heat resistance as to resist this high annealing temperature is used for the ferromagnetic layer of the memory element, excellent MR properties are difficult to be achieved.

However, studies made by the present inventors have proved that addition of Ta, which has a high melting point, to a ferromagnetic layer included in a memory layer offers the following advantages. Specifically, the heat resistance of the magnetic substance of the ferromagnetic layer can be improved, and diffusion of elements between the ferromagnetic layer and neighboring layers can be suppressed.

The B content needs to be at least 10 at % in order to ensure the heat resistance against temperatures up to 400° C. However, if the B content is over 30 at %, the ferromagnetic layer is difficult to ensure the saturation magnetization necessary for construction of a memory element although the layer is allowed to exist as a magnetic layer. Therefore, the B content is set to a value equal to or smaller than 30 at %.

A CoFe alloy is used as the material of a memory layer in a typical MRAM, and a tendency is found that higher Fe content in the CoFe alloy leads to a larger MR ratio and improved spin injection efficiency.

However, in actual, the decrease amount of the reversal current density is smaller than the amount that is expected from the increase amount of the MR ratio.

In order to apply a sufficient writing current to a memory element, the area-resistance product of the tunnel insulating layer (tunnel barrier layer) needs to be decreased.

Specifically, the area-resistance product of the tunnel insulating layer is set to several tens of Ωμm² or less in terms of acquisition of the current density necessary for reversal of the magnetization direction of the memory layer due to spin injection.

When a tunnel insulating layer formed of an MgO film is employed, the film thickness of the MgO film needs to be 1.5 nm or smaller in order to obtain the area-resistance product within the above-described range.

Furthermore, it is desirable to decrease the size of the memory element so that the magnetization direction of the memory layer can be reversed easily with a small current.

Therefore, preferably the area of the memory element is set to 0.04 μm² or smaller.

In the present invention, at least one ferromagnetic layer included in a memory layer is composed mainly of CoFeTa or CoFeTaB of which composition is congruous with the above-described composition ranges.

Specifically, one or all of ferromagnetic layers included in a memory layer are composed mainly of CoFeTa or CoFeTaB of which composition is congruous with the above-described composition ranges.

It is also possible to stack a ferromagnetic layer composed mainly of CoFeTa or CoFeTaB having a composition congruous with the above-described composition ranges and another ferromagnetic layer having a different material or composition directly on top of one another. Alternatively, it is also possible to stack a ferromagnetic layer and a soft magnetic layer on top of one another, or stack plural ferromagnetic layers with the intermediary of soft magnetic layers and non-magnetic layers thereamong. Such multilayer structures also offer the above-described advantages of the present invention.

When plural ferromagnetic layers are stacked with the intermediary of non-magnetic layers thereamong in particular, adjustment of the strength of interaction among the ferromagnetic layers is allowed. Therefore, even when the size of the memory element is on the order of sub microns or smaller, the magnetization reversal current can advantageously be suppressed so as not to increase. As the material of the non-magnetic layers that intervene among the ferromagnetic layers, any of the following elements or an alloy of any of these elements can be used: Ru, Os, Re, Ir, Au, Ag, Cu, Al, Bi, Si, B, C, Cr, Ta, Pd, Pt, Zr, Hf, W, Mo, and Nb.

Typically, a memory layer is composed mainly of ferromagnetic materials such as Co, Fe, Ni and Gd, and is formed by stacking at least one layer that is composed of an alloy of at least two of these ferromagnetic materials.

If a ferromagnetic layer included in a memory layer is composed mainly of CoFeTa or CoFeTaB having a composition congruous with the above-described composition ranges, the ferromagnetic layer may employ a material that includes CoFeTa or CoFeTaB as the main component with an additive material. Examples of the additive material include magnetic elements such as Ni and Gd, and other elements such as C, N, Si, P, Al, Ta, No, Cr, Nb, Cu, Zr, W, V, Hf, Mn, and Pd.

As the material of a ferromagnetic layer in a memory layer other than the ferromagnetic layer composed mainly of CoFeTa or CoFeTaB and as the material of a ferromagnetic layer in a magnetization pinned layer, any of the following materials is available: an NiFe alloy; an CoFe alloy; an CoFeNi alloy; a material arising from addition of at least one element selected from Si and B to at least one element selected from Co, Fe and Ni; a material arising from further addition, to the previously-mentioned material, of at least one element selected from P, Al, Mo, Nb and Mn; an amorphous material arising from addition of at least one element selected from Zr, Hf, Nb, Ta, and Ti to Co; and Huesler materials such as CoMnSi, CoMnAl, and CoCrFeAl.

It is desirable that the magnetization pinned layer have unidirectional anisotropy and the memory layer have uniaxial anisotropy. Furthermore, it is preferable that the film thicknesses of the magnetization pinned layer and memory layer be in the range from 1 nm to 30 nm.

Other configurations of the memory element may be the same as publicly-known configurations of memory elements in related art for recording information by use of spin injection.

The magnetization direction of the magnetization pinned layer is fixed through use of a ferromagnetic layer, or by utilizing antiferromagnetic coupling between an antiferromagnetic layer and a ferromagnetic layer.

The magnetization pinned layer is formed of a single ferromagnetic layer, or has a synthetic ferri-magnetic structure in which plural ferromagnetic layers are stacked with the intermediary of non-magnetic layers thereamong.

When the magnetization pinned layer has a synthetic ferri-magnetic structure, the sensitivity of the magnetization pinned layer to an external magnetic field can be lowered. Therefore, unnecessary magnetization fluctuation of the magnetization pinned layer due to an external field can be suppressed, which allows stable operation of the memory element. Furthermore, the adjustment of the film thickness of the respective ferromagnetic layers is allowed, and thus a leakage magnetic field from the magnetization pinned layer can be suppressed.

As the material of the ferromagnetic layers included in a magnetization pinned layer with a synthetic ferri-magnetic structure, any of Co, CoFe, CoFeB, and the like can be used. As the material of the non-magnetic layers, any of Ru, Re, Ir, Os, and the like can be used.

Examples of the material of the antiferromagnetic layer include magnetic substances such as an FeMn alloy, a PtMn alloy, a PtCrMn alloy, an NiMn alloy, an IrMn alloy, NiO, and Fe₂O₃.

In addition, these magnetic substances may be provided with any of additive non-magnetic elements such as Ag, Cu, Au, Al, Si, Bi, Ta, B, C, O, N, Pd, Pt, Zr, Hf, Ir, W, Mo, and Nb, so that the magnetic properties can be adjusted and other various properties such as the crystalline structure, crystallinity, and substance stability can be adjusted.

In the film structure of the memory element, whether the memory layer is provided above or below the magnetization pinned layer does not matter at all.

For retrieval of information recorded in the memory layer of the memory element, a magnetic layer serving as a reference of information may be provided near the memory layer of the memory element with the intermediary of a thin insulating film therebetween, and information may be retrieved based on a ferromagnetic tunnel current that flows through the insulating layer. Alternatively, information may be retrieved based on a magnetoresistance effect.

Embodiments of the present invention will be described below.

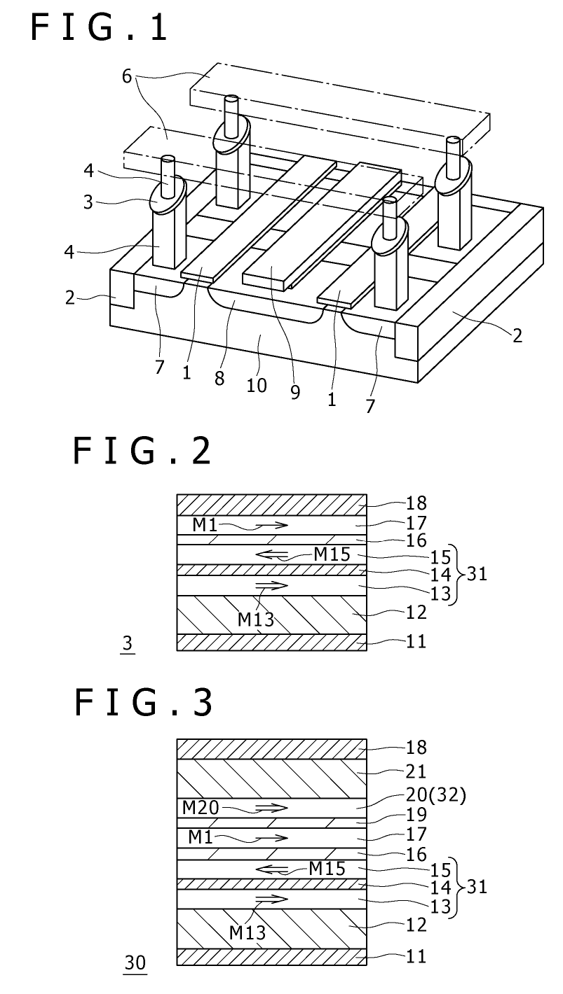

FIG. 1 is a schematic structural diagram (perspective view) of a memory according to one embodiment of the invention.

In this memory, memory elements that can hold information based on the magnetization state are arranged near the intersections between two kinds of address lines (e.g., word lines and bit lines) perpendicular to each other.

Specifically, in the respective regions separated by element isolation layers 2 in a semiconductor base 10 such as a silicon substrate, drain regions 8, source regions 7, and gate electrodes 1 included in selection transistors for selecting the respective memory cells are formed. Of these components, the gate electrode 1 serves also as one address line (e.g., the word line) extending in the anteroposterior direction in the drawing.

The drain region 8 is formed in common to two selection transistors that are laterally arranged in the drawing, and is connected to an interconnect 9.

A memory element 3 is provided between the source region 7 and the other address line (e.g., the bit line) 6 that is provided above and extends in the lateral direction in the drawing. The memory element 3 includes a memory layer that is formed of a ferromagnetic layer of which magnetization direction is reversed due to spin injection.

The memory element 3 is disposed near the intersection between two kinds of the address lines 1 and 6.

The memory element 3 is coupled to the bit line 6 and the source region 7 via upper and lower contact layers 4, respectively.

This structure allows a current to flow through the memory element 3 in a vertical direction via the two bit line 6 and the interconnect 9 so that the magnetization direction in the memory layer can be reversed due to spin injection.

FIG. 2 is a sectional view of the memory element 3 in the memory of the present embodiment.

As shown in FIG. 2, the memory element 3 includes a memory layer 17 in which the direction of magnetization Ml is reversed due to spin injection, and a magnetization pinned layer 31 provided below the memory layer 17. An antiferromagnetic layer 12 is provided below the magnetization pinned layer 31, and the magnetization direction of the magnetization pinned layer 31 is fixed due to the antiferromagnetic layer 12.

An insulating film 16 serving as a tunnel barrier layer (tunnel insulating layer) is provided between the memory layer 17 and the magnetization pinned layer 31, so that the memory layer 17 and the magnetization pinned layer 31 construct an MTJ element.

An underlying layer 11 is formed below the antiferromagnetic layer 12, and a cap layer 18 is formed on the memory layer 17.

The magnetization pinned layer 31 has a synthetic ferri-magnetic structure.

Specifically, the magnetization pinned layer 31 has a structure in which two ferromagnetic layers 13 and 15 are stacked with the intermediary of a non-magnetic layer 14 therebetween so as to be antiferromagnetically coupled to each other.

Since the respective ferromagnetic layers 13 and 15 of the magnetization pinned layer 31 form a synthetic ferri-magnetic structure, the directions of magnetizations M13 and M15 of the ferromagnetic layers 13 are 15 are the right and left directions, respectively, in the drawing, and hence are opposite to each other.

Thus, the magnetic flux leaked from the ferromagnetic layers 13 and 15 of the magnetization pinned layer 31 cancels each other.

The present embodiment employs a configuration in which the memory layer 17 is composed mainly of CoFeTa and has Ta content in the range from 1 at % to 20 at %. Alternatively, the embodiment employs another configuration in which the memory layer 17 is composed mainly of CoFeTaB, and the Ta content and B content in the memory layer 17 are in the range from 1 at % to 20 at %, and in the range from 10 at % to 30 at %, respectively.

The ferromagnetic layer composed mainly of CoFeTa or CoFeTaB with a composition in the above-described composition ranges may contain any of Fe, Co, and Gd as other elements. Furthermore, the ferromagnetic layer may contain any of other transition metals such as Mo, Mn, Cu, Nb, and Zr, and any of light elements such as B and C.

Furthermore, it is more preferable that the insulating layer 16 as the intermediate layer be formed of a magnesium oxide layer. Instead of the magnesium oxide layer, the intermediate layer may be formed of any of various insulators, dielectrics, and semiconductors such as aluminum oxide, aluminum nitride, SiO₂, Bi₂O₃, MgF₂, CaF, SrTiO₂, AlLaO₃, and AlNO.

As the material of the non-magnetic layer 14 included in the synthetic ferri-magnetic structure of the magnetization pinned layer 31, any of the above-described materials can be used. The film thickness of the non-magnetic layer 14 depends on the material thereof, but preferably is in the range from about 0.5 nm to about 2.5 nm.

As the material of the antiferromagnetic layer 12, any of the above-described materials can be used.

The ferromagnetic layers 13 and 15 of the magnetization pinned layer 31 can be composed of an alloy material including one or more kinds of Fe, Ni, Co, and Gd for example. Furthermore, the layers 13 and 15 may contain any of transition metal elements such as Nb and Zr, and any of light elements such as B and C.

The film thicknesses of the ferromagnetic layers 13 and 15 of the magnetization pinned layer 31 can be adjusted adequately, and preferably are in the range from 1 nm to 5 nm.

The memory element 3 of the present embodiment can be manufactured by consecutively forming the respective components from the underlying layer 11 to the cap layer 18 in vacuum equipment, and then forming the pattern of the memory element 3 through processing such as etching.

According to an embodiment of the present embodiment, the memory layer 17 of the memory element 3 is composed mainly of CoFeTa and has Ta content in the range from 1 at % to 20 at %. Alternatively, the memory layer 17 is composed mainly of CoFeTaB, and the Ta content and B content in the memory layer 17 are in the range from 1 at % to 20 at %, and in the range from 10 at % to 30 at %, respectively. Thus, the spin injection efficiency can be enhanced while a high MR ratio is maintained, to thereby significantly reduce the current density necessary for reversal of the direction of the magnetization M1 in the memory layer 17 due to spin injection.

In addition, the heat resistance of the ferromagnetic layer is enhanced, and thus the ferromagnetic layer can endure annealing at 400° C. without its magnetic properties being deteriorated.

This feature offers an advantage that a typical semiconductor MOS forming process can be applied to manufacturing of a memory including the memory element 3, which permits the memory having the memory element 3 of the present embodiment to be used as a general-purpose memory.

Furthermore, if the insulating layer 16 as the intermediate layer is formed of a magnesium oxide layer in the present embodiment, an enhanced magnetoresistance change ratio (MR ratio) can be achieved.

This enhancement of the MR ratio also can improve the spin injection efficiency to thereby reduce the current density necessary for reversal of the direction of the magnetization M1 in the memory layer 17.

Consequently, a highly reliable memory that stably operates can be achieved, and power consumption of a memory including the memory element 3 can be decreased.

FIG. 3 is a sectional view illustrating a memory element constructing a memory according to another embodiment of the invention.

A memory element 30 includes a memory layer 17 in which the direction of magnetization M1 is reversed due to spin injection, and magnetization pinned layers 31 and 32 provided below and above the memory layer 17, respectively. That is, the upper and lower two magnetization pinned layers 31 and 32 are provided for the memory layer 17.

The upper magnetization pinned layer 32 is formed of a single ferromagnetic layer 20.

An insulating film 19 serving as a tunnel barrier layer (tunnel insulating layer) is provided between the memory layer 17 and the magnetization pinned layer 32, so that the memory layer 17 and the magnetization pinned layer 32 construct an MTJ element.

An antiferromagnetic layer 21 is provided on the magnetization pinned layer 32, and the direction of magnetization M20 in the ferromagnetic layer 20 of the magnetization pinned layer 32 is fixed due to the antiferromagnetic layer 21.

A cap layer 18 is formed on the antiferromagnetic layer 21.

The present embodiment has a configuration in which the memory layer 17 is composed mainly of CoFeTa and has Ta content in the range from 1 at % to 20 at %, or a configuration in which the memory layer 17 is composed mainly of CoFeTaB, and the Ta content and B content in the memory layer 17 are in the range from 1 at % to 20 at %, and in the range from 10 at % to 30 at %, respectively.

Furthermore, it is more preferable that the insulating layers 16 and 19 as the intermediate layers be formed of a magnesium oxide layer.

The ferromagnetic layer composed mainly of CoFeTa or CoFeTaB with a composition in the above-described composition ranges may contain any of Fe and Gd as other elements. Furthermore, the ferromagnetic layer may contain any of other transition metals such as Mo, Mn, Cu, Nb, and Zr, and any of light elements such as B and C.

Other parts of the memory element 30 are the same as those of the memory element 3 shown in FIG. 2, and therefore are given the same numerals with overlapping descriptions therefor being omitted.

Furthermore, with use of the memory elements 30 of the present embodiment, a memory similar to the memory shown in FIG. 1 can be constructed.

Specifically, the memory elements 30 are arranged at the intersections between two kinds of address lines to thereby construct a memory. In the memory, a current in a vertical direction (layer-stacking direction) is applied to the memory element 30 via the two kinds of the address lines, and thus the direction of the magnetization M1 of the memory layer 17 is reversed due to spin injection so that information can be recorded in the memory element 30.

According to an embodiment of the present embodiment, the memory layer 17 of the memory element 30 is composed mainly of CoFeTa and has Ta content in the range from 1 at % to 20 at %. Alternatively, the memory layer 17 is composed mainly of CoFeTaB, and the Ta content and B content in the memory layer 17 are in the range from 1 at % to 20 at %, and in the range from 10 at % to 30 at %, respectively. Thus, the spin injection efficiency can be enhanced while a high MR ratio is ensured, to thereby significantly reduce the current density necessary for reversal of the direction of the magnetization Ml in the memory layer 17 due to spin injection.

In addition, the heat resistance of the ferromagnetic layer is enhanced, and thus the ferromagnetic layer can endure annealing at 400° C. without its magnetic properties being deteriorated.

This feature offers an advantage that a typical semiconductor MOS forming process can be applied to manufacturing of a memory including the memory element 30. The memory having the memory element 30 of the present embodiment can be used as a general-purpose memory.

Furthermore, if the insulating layers 16 and 19 as the intermediate layers are formed of a magnesium oxide layer in the present embodiment, an enhanced magnetoresistance change ratio (MR ratio) can be achieved.

This enhancement of the MR ratio also can improve the spin injection efficiency to thereby reduce the current density necessary for reversal of the direction of the magnetization M1 in the memory layer 17.

Moreover, in the present embodiment, the magnetization pinned layers 31 and 32 are provided below and above the memory layer 17 with the intermediary of the insulating layers 16 and 19 therebetween, respectively. The operation of this structure also can reduce the current necessary for reversal of the direction of the magnetization M1 in the memory layer 17.

Consequently, a highly reliable memory that stably operates can be achieved, and power consumption of a memory including the memory element 30 can be decreased.

### WORKING EXAMPLE

The materials, film thicknesses, and so on of the respective layers were specifically chosen for the structure of the memory element of the present invention, and the properties of the memory element were investigated.

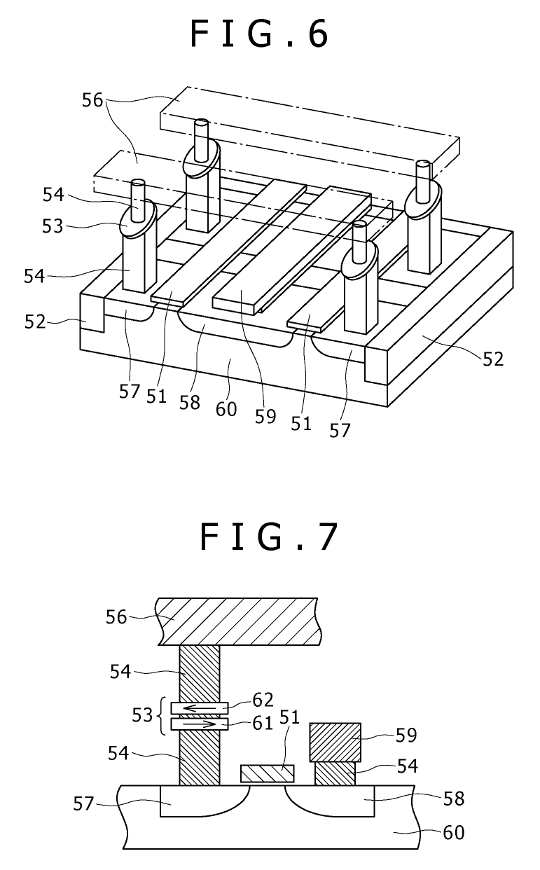

An actual memory includes, besides memory elements, semiconductor circuits for switching and so on as shown in FIGS. 1 and 6. However, in the working examples, studies were made on a wafer on which memory elements have been formed in order to investigate the magnetoresistance properties of the memory layer.

<First Experiment>

A thermally oxidized film with a thickness of 300 nm was formed on a silicon substrate with a thickness of 0.725 mm, and then the memory element 3 having the structure of FIG. 2 is formed on the thermally oxidized film.

The specific materials and film thicknesses of the respective layers in the memory element 3 having the structure shown in FIG. 2 were as follows. The underlying film 11 was formed of a Ta film with a thickness of 3 nm, and the antiferromagnetic layer 12 a PtMn film of 20 nm. The ferromagnetic layers 13 and 15 of the magnetization pinned layer 31 were formed of a CoFe film of 2 nm and a CoFeB film of 2.5 nm, respectively. The non-magnetic layer 14 included in the magnetization pinned layer 31 with a synthetic ferri-magnetic structure was formed of a Ru film with a thickness of 0.8 nm. The insulating layer (barrier layer) 16 serving as a tunnel insulating layer was formed of a magnesium oxide film with a thickness of 0.9 nm. The memory layer 17 and the cap layer 18 were formed of a CoFeTa film of 3 nm and a Ta film of 5 nm, respectively. Furthermore, a Cu film (not shown, serving as a word line to be described later) with a thickness of 100 nm is provided between the underlying film 11 and the antiferromagnetic layer 12.

In this film structure, the composition of the PtMn film was Pt50Mn50 (at %), and the composition of the CoFe film was Co90Fe10 (at %).

The ratio of Co to Fe in the CoFeTa film was 80:20.

The respective layers other than the insulating layer 16 formed of a magnesium oxide film were deposited by DC magnetron sputtering.

The insulating layer 16 formed of a magnesium oxide (MgO) film was deposited by RF magnetron sputtering.

After the deposition of the respective layers in the memory element 3, annealing was carried out in a magnetic annealing furnace with 10 kOe at 360° C. for two hours to thereby implement ordering heat treatment for the PtMn film of the antiferromagnetic layer 12.

Subsequently, the word line part was covered by a mask through photolithography, and then selective etching was carried out for the multilayer film other than the word line part with Ar plasma, so that the word line (lower electrode) was formed. By this etching, the region other than the word line part was etched to a depth of 5 nm of the substrate.

Thereafter, a mask for the pattern of the memory element 3 was formed by use of an electron-beam drawing apparatus, followed by selective etching for the multilayer film, which resulted in the formation of the memory element 3. For the region other than the memory element part, etching was proceeded to directly above the Cu layer as the word line.

Note that a memory element for property evaluation needs to be provided with a current sufficiently large to generate spin torque necessary for magnetization reversal, and therefore the resistance of the tunnel insulating layer in the memory element needs to be suppressed. Therefore, the pattern of the memory element 3 was formed into an elliptical shape with a size of 0.09 μm (minor axis) by 0.18 μm (major axis), so that the area-resistance product (Ωμm²) of the memory element 3 was 30 Ωμm².

Subsequently, the region other than the memory element part was isolated by depositing thereon an Al₂O₃ film with a thickness of about 100 nm by sputtering.

Thereafter, a bit line to serve as the upper electrode and a pad for measurement were formed by use of photolithography.

In this manner, a sample of the memory element 3 was fabricated.

By the above-described manufacturing method, plural samples of the memory element 3 were fabricated in which the addition amounts of Ta in the CoFeTa film of the memory layer 17 were different from each other on each sample basis.

Specifically, the samples having the following Ta addition amounts were fabricated: 0 (Co80Fe20), 2, 5, 10, 15, 20, 25, and 30 at %.

<Second Experiment>

For the memory element 3 having the structure shown in FIG. 2, the materials and film thicknesses of the respective layers were chosen as follows. The underlying film 11 was formed of a Ta film with a thickness of 3 nm, and the antiferromagnetic layer 12 a PtMn film of 20 nm. The ferromagnetic layers 13 and 15 of the magnetization pinned layer 31 were formed of a CoFe film of 2 nm and a CoFeB film of 2.5 nm, respectively. The non-magnetic layer 14 included in the magnetization pinned layer 31 with a synthetic ferri-magnetic structure was formed of a Ru film with a thickness of 0.8 nm. The insulating layer (barrier layer) 16 serving as a tunnel insulating layer was formed of a magnesium oxide film with a thickness of 0.8 nm. The memory layer 17 and the cap layer 18 were formed of a CoFeTaB film of 3 nm and a Ta film of 5 nm, respectively.

The ratio of Co to Fe in the CoFeTaB film was 80:20.

Other configurations and the manufacturing method of the memory element 3 were the same as those of the memory element 3 of the first experiment.

By the above-described manufacturing method, plural samples of the memory element 3 were fabricated in which the addition amounts of Ta and B in the CoFeTaB film of the memory layer 17 were different from each other on each sample basis.

Specifically, the samples having the following Ta and B addition amounts were fabricated: 0, 5, 10, 15, 20, 25, and 30 at % for Ta, and 5, 10, 20, 30, and 40 at % for B. That is, the total number of the fabricated samples was 7×5=35.

For the respective samples of the memory element 3 fabricated in the first and second experiments, the following property evaluation was carried out.

Prior to the measurement, the measurement system was configured to allow application of a magnetic field from the external to the memory element 3 so that the values of reversal currents in the positive and negative directions could be controlled so as to be symmetric. Furthermore, the voltage applied to the memory element 3 was set lower than 1 V, which is within the range of voltages that do not cause the breakdown of the insulating layer 16.

Measurement of Reversal Current Values and MR Ratios

Current was applied to the memory elements 3 so that the resistance values of the memory elements 3 were measured. In this resistance measurement, the temperature was adjusted to a room temperature of 25° C., and the bias voltage applied to terminals of the word line and bit line was set to 10 mV. This resistance measurement was carried out with the amount of current flowing through the memory elements 3 being changed, and thus resistance-current curves were obtained from the measurement results. This measurement for obtaining the resistance-current curves was implemented for the currents of the both polarities (in the positive and negative directions).

From the resistance-current curves, the current value that offers a resistance change was obtained, and was defined as the reversal current value that yields the reversal of the magnetization direction. The reversal current values were obtained for the currents of the both polarities.

Subsequently, the average of the absolute values of the reversal current values of the both polarities was calculated, and this average was divided by the element area to thereby calculate the magnetization reversal current density (MA/cm²).

In addition, the ratio of the following resistance values was calculated, and was defined as the MR ratio (TMR ratio): the resistance value when the direction of the magnetization M15 in the ferromagnetic layer 15 of the magnetization pinned layer 31, which is closer to the memory layer 17, was antiparallel to the direction of the magnetization M1 of the memory layer 17 and hence the resistance was large; and the resistance value when the directions of these magnetizations M15 and M1 were parallel and hence the resistance was small.

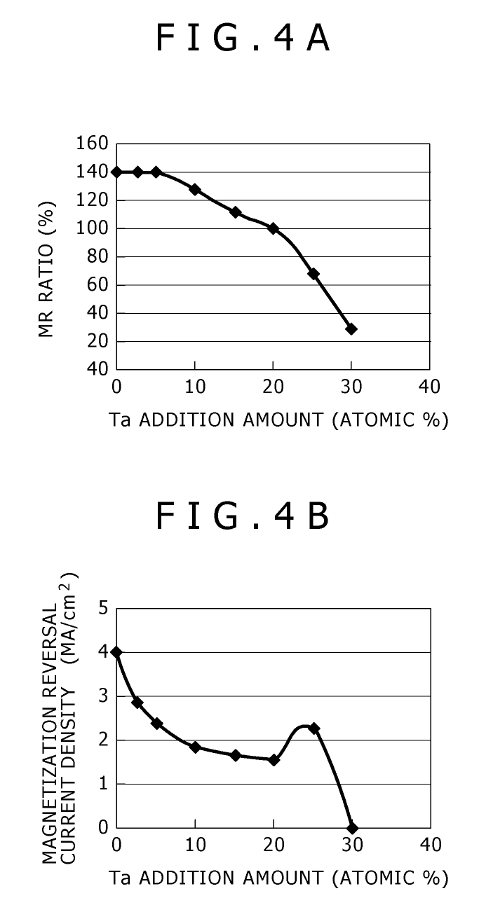

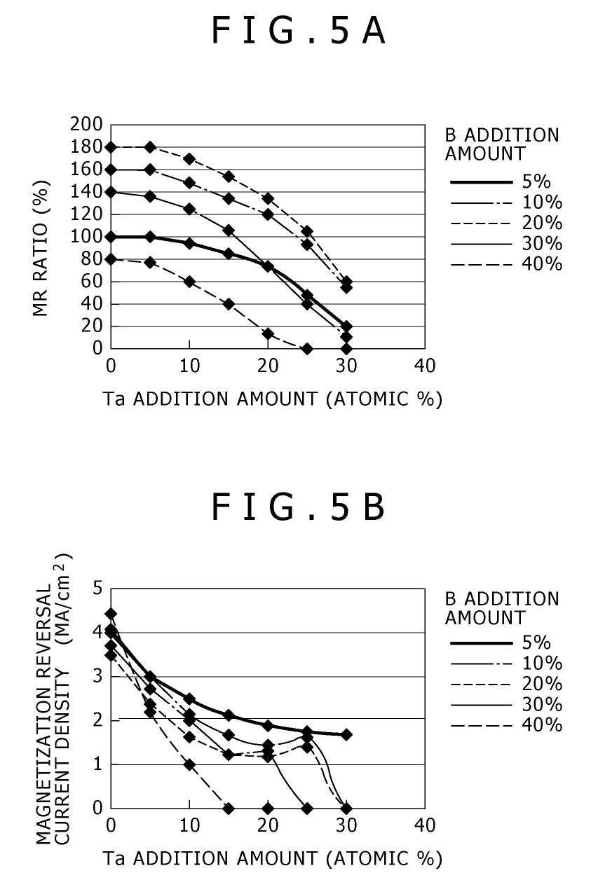

The measurement results on the respective samples of the first experiment are shown in FIGS. 4A and 4B, and those on the respective samples of the second experiment are shown in FIGS. 5A and 5B. FIGS. 4A and 5A show the relationship between the addition amount of Ta (at %) (and the addition amount of B (at %) in FIG. 5A) and the MR ratio. FIGS. 4B and 5B show the relationship between the addition amount of Ta (at %) (and the addition amount of B (at %) in FIG. 5B) and the magnetization reversal current density.

FIGS. 4A and 5A indicate the following fact. Specifically, an MR ratio larger than 75% is ensured when in the memory elements 3 of the first and second experiments, the Ta addition amount in the CoFeTa or CoFeTaB layer of the memory layer 17 is in the range from 1 at % to 20 at %, and the B addition amount is in the range from 10 at % to 30 at %, i.e., when these addition amounts are within the ranges specified in the present invention.

An MR ratio of 75% is the necessary value for the memory to ensure sufficient reading speed and a margin of error. Even if an improvement of the reversal current density results in a decrease of the MR ratio, the memory is allowed to have requisite properties as long as the MR ratio is at least 75%.

FIGS. 4B and 5B indicate the following fact. Specifically, the magnetization reversal current density is smaller than 3 MA/cm², which allows achievement of a memory utilizing spin injection, when in the memory elements 3 of the first and second experiments, the Ta addition amount in the CoFeTa or CoFeTaB layer of the memory layer 17 is in the range from 1 at % to 20 at %, and the B addition amount is in the range from 10 at % to 30 at %, i.e., when these addition amounts are within the ranges specified in the present invention.

The above-described results show the following fact. Specifically, even when the ferromagnetic layer of the memory layer 17 contains Ta and hence a decrease of the MR ratio is found, an MR ratio of 75%, which is the necessary value for the reading operation of the memory, can be maintained by adjusting the composition of the ferromagnetic layer so that the composition falls within the composition ranges specified in the present invention. This composition adjustment also allows a great decrease of the reversal current density, which has been the largest challenge. In addition, employing the configuration of the present invention allows fabrication of a memory element that can write information with a comparatively low current density of 3 MA/cm² or less, and therefore can achieve a novel low-power-consumption magnetic memory employing spin injection magnetization reversal.

The present invention is not limited to the film structures of the memory elements 3 and 30 shown in the above-described embodiments, but may employ other various film structures.

In the above-described embodiments, the magnetization pinned layer 31 has a synthetic ferri-magnetic structure including the ferromagnetic layers 13 and 15 and the non-magnetic layer 14. However, the magnetization pinned layer may be formed of a single ferromagnetic layer for example.

The present invention is not limited to the above-described embodiments but may employ other various configurations without departing from the scope of the invention.

What is claimed is:

1. A memory element comprising:
a memory layer that holds information based on a magnetization state of a magnetic substance; and
a magnetization pinned layer that is provided for the memory layer with intermediary of an intermediate layer therebetween, the intermediate layer being composed of an insulator; wherein
spin-polarized electrons are injected in a layer-stacking direction to thereby change a direction of magnetization of the memory layer, so that information is recorded in the memory layer, and
at least one ferromagnetic layer included in the memory layer is composed mainly of CoFeTa, and has Ta content in a range from 1 atomic percent (at %) to 20 at %.

2. The memory element according to claim 1, wherein
at least one ferromagnetic layer included in the memory layer is composed mainly of CoFeTaB, and has Ta content in a range from 1 at % to 20 at % and B content in a range from 10 at % to 30 at %.

3. The memory element according to claim 1, wherein
the intermediate layer is composed of magnesium oxide.

4. A memory comprising:
a memory element that includes a memory layer for holding information based on a magnetization state of a magnetic substance; and
two kinds of interconnects that intersect with each other; wherein
the memory element includes a magnetization pinned layer that is provided for the memory layer with intermediary of an intermediate layer composed of an insulator therebetween,
spin-polarized electrons are injected in a layer-stacking direction to thereby change a direction of magnetization of the memory layer, so that information is recorded in the memory layer,
at least one ferromagnetic layer included in the memory layer is composed mainly of CoFeTa, and has Ta content in a range from 1 at % to 20 at %,
the memory element is disposed between the two kinds of interconnects and near an intersection of the two kinds of interconnects, and
a current in the layer-stacking direction flows through the memory element via the two kinds of interconnects.

5. The memory according to claim 4, wherein
at least one ferromagnetic layer included in the memory layer in the memory element is composed mainly of CoFeTaB, and has Ta content in a range from 1 at % to 20 at % and B content in a range from 10 at % to 30 at %.
